(19) United States
(12) Patent Application Publication
(10) Pub. No.: US 2008/0068014 A1
(43) Pub. Date: Mar. 20, 2008

(54) Magnetic Resonance Imaging With Adjustment for Magnetic Resonance Decay

(75) Inventor: Wayne R. Dannels, Mentor, OH (US)

Correspondence Address: PHILIPS INTELLECTUAL PROPERTY & STANDARDS, 595 MINER ROAD, CLEVELAND, OH, 44143, US

(73) Assignee: Koninklijke Philips Electronics N.V., Eindhoven (NL)

(21) Appl. No.: 11/815,869

(22) PCT Filed: Feb. 7, 2006
(86) PCT No.: PCT/IB06/50400

§ 371 Date: Aug. 9, 2007

Related U.S. Application Data
(60) Provisional application No. 60/652,086, filed on Feb. 11, 2005.

(51) Int. Cl. G01R 33/48; G01R 33/561

(52) U.S. Cl. 324/312; 702/57

(57) ABSTRACT

In a magnetic resonance imaging method, a plurality of at least partially overlapping k-space datasets are acquired. Each of at least partially overlapping k-space datasets includes k-space samples acquired at different measuring times including common locations in k-space that are sampled at different measuring times in the acquired k-space datasets. The plurality of at least partially overlapping k-space datasets are reconstructed to produce a reconstructed image representative of a selected measuring time. During the reconstructing, at least one of k-space values and intermediate image element values are interpolated or extrapolated to the selected measuring time based on the sampling at different measuring times of the common locations in k-space.

The following relates to the magnetic resonance arts. It finds particular application in magnetic resonance imaging of materials having short magnetic resonance decay times, such as lung tissue, atherosclerotic plaque, tendon, imaging of tissues infused with high concentrations of magnetic contrast agent, imaging of materials using nuclear magnetic resonances from atoms heavier than hydrogen, and so forth, and will be described with particular reference thereto. More generally, it finds application in magnetic resonance systems for imaging, spectroscopy, and so forth.

Short magnetic resonance decay times impose restrictions upon the readout portion of the imaging sequence. The echo time should be comparable with the rapid decay time of the magnetic resonance (such as the T2 decay time or the T2* decay time). For short resonance decay times, the magnetic resonance signal can decay substantially between the beginning and the end of the readout.

Radial sampling is sometimes used to advantage for imaging materials having short magnetic resonance decay time. Each radial readout typically starts at the k-space center and moves outward, so that the central portion of k-space is acquired first. Since the central portion of k-space provides low frequency image components that define the coarse features of the overall image, accuracy in acquiring the central k-space region reduces the effect of the rapid magnetic resonance signal decay on image quality.

Pauly et al., U.S. Pat. No. 5,025,216, discloses using short shaped radio frequency pulses to reduce the latency time between the transmit and receive phases of the magnetic resonance imaging sequence. Still further improvement in imaging using short echo times can be achieved using three-dimensional imaging with non-selective RF excitation which omits slice-selective magnetic field gradients.

These techniques are directed toward shortening the interval between radio frequency excitation and the start of the readout of k-space samples.

However, image degradation can still result from decay of the magnetic resonance signal over the readout time. Various techniques are available for shortening the readout time; however, these techniques typically introduce image degradation such as reduced spatial resolution or increased artifacts. Further shortening the readout time may also be unfeasible if it would cause the signal-to-noise-ratio of the image to degrade beyond acceptable limits.

The following contemplates improved apparatuses and methods that overcome the aforementioned limitations and others.

According to one aspect, a magnetic resonance imaging method is provided. A plurality of at least partially overlapping k-space datasets are acquired. Each of the at least partially overlapping k-space datasets includes k-space samples acquired at different measuring times including common locations in k-space that are sampled at different measuring times in the acquired k-space datasets. The plurality of at least partially overlapping k-space datasets are reconstructed to produce a reconstructed image representative of a selected measuring time. During the reconstructing, at least one of k-space values and intermediate image element values are interpolated or extrapolated to the selected measuring time based on the sampling at different measuring times of the common locations in k-space.

According to another aspect, a magnetic resonance imaging apparatus is provided for performing a magnetic resonance imaging method including: acquiring a plurality of at least partially overlapping k-space datasets each including k-space samples acquired at different measuring times and including common locations in k-space that are sampled at different measuring times in the acquired k-space datasets; reconstructing the plurality of at least partially overlapping k-space datasets to produce a reconstructed image representative of a selected measuring time; and during the reconstructing, interpolating or extrapolating at least one of k-space values and intermediate image element values to the selected measuring time based on the sampling at different measuring times of the common locations in k-space.

One advantage resides in improved image quality for materials and imaging subjects in which the magnetic resonance signal decays rapidly.

Another advantage resides in reduced time blurring due to decay of the magnetic resonance signal during readout.

Another advantage resides in enabling longer k-space sampling readouts with reduced image degradation due to decay of the magnetic resonance signal during the lengthened readout.

Numerous additional advantages and benefits will become apparent to those of ordinary skill in the art upon reading the following detailed description.

The invention may take form in various components and arrangements of components, and in various process operations and arrangements of process operations. The drawings are only for the purpose of illustrating preferred embodiments and are not to be construed as limiting the invention.

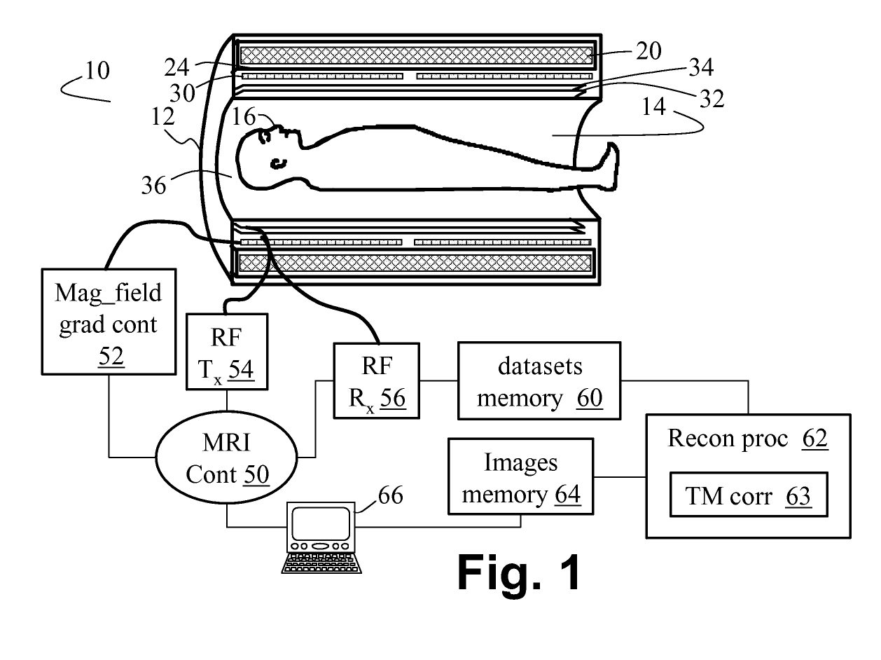

FIG. 1 diagrammatically shows a magnetic resonance imaging system for imaging materials and imaging subjects having short magnetic resonance decay times.

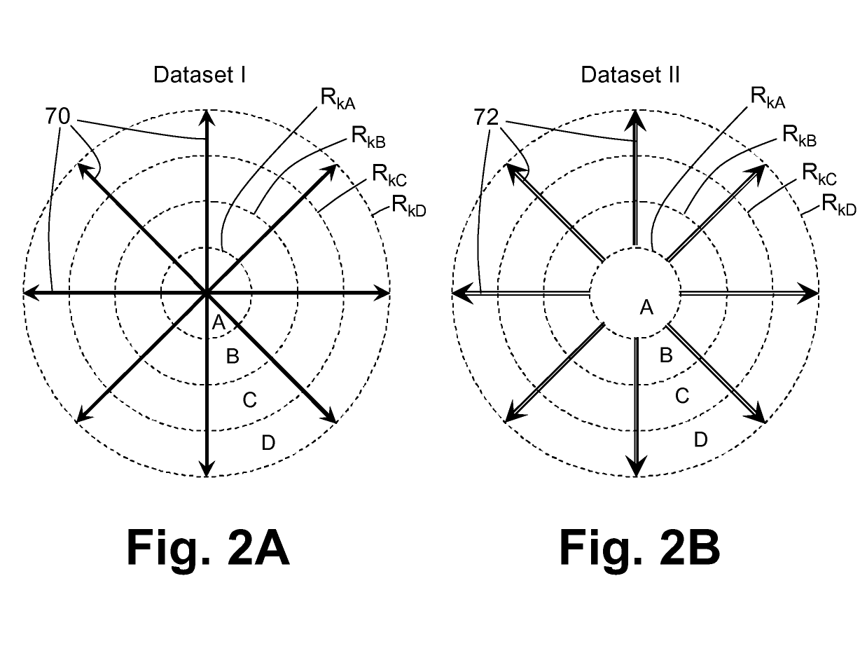

FIGS. 2A and 2B diagrammatically show radial trajectories of a first k-space dataset (“Dataset I”) and of a second k-space dataset (“Dataset II”) used herein to illustrate one reconstruction method that corrects for differences in measuring time amongst the k-space samples. Dataset I and Dataset II partially overlap, and the overlapping portions of Datasets I and II have different measuring times.

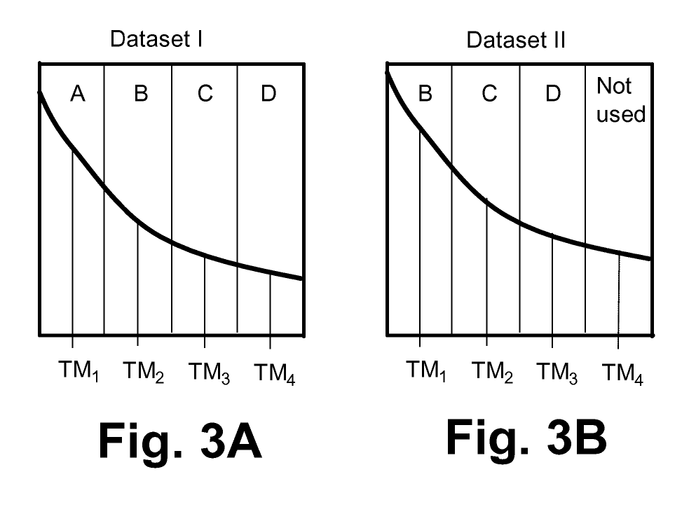

FIGS. 3A and 3B diagrammatically show magnetic resonance signal decay over the time interval of a radial readout line for Dataset I and Dataset II, respectively.

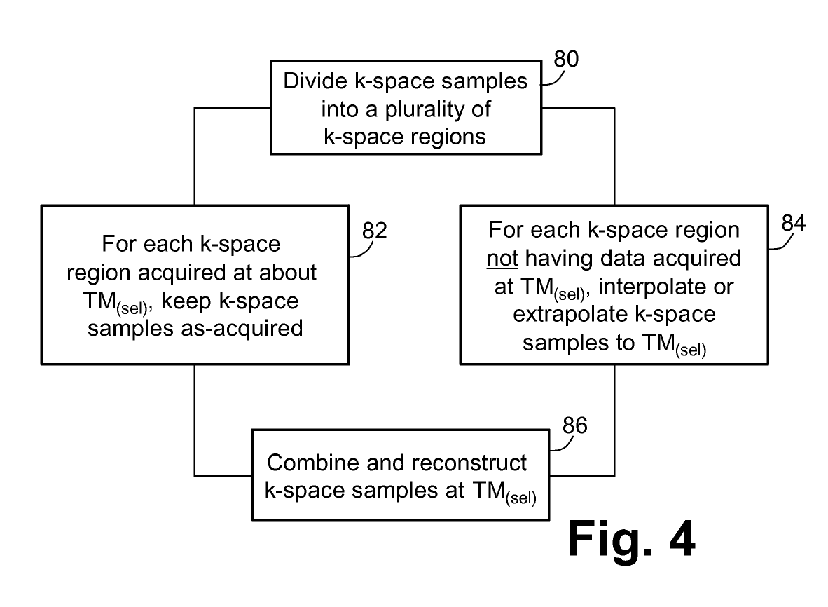

FIG. 4 diagrammatically shows a reconstruction method in which measuring times of the commonly measured k-space samples are interpolated or extrapolated in k-space before producing a reconstructed image.

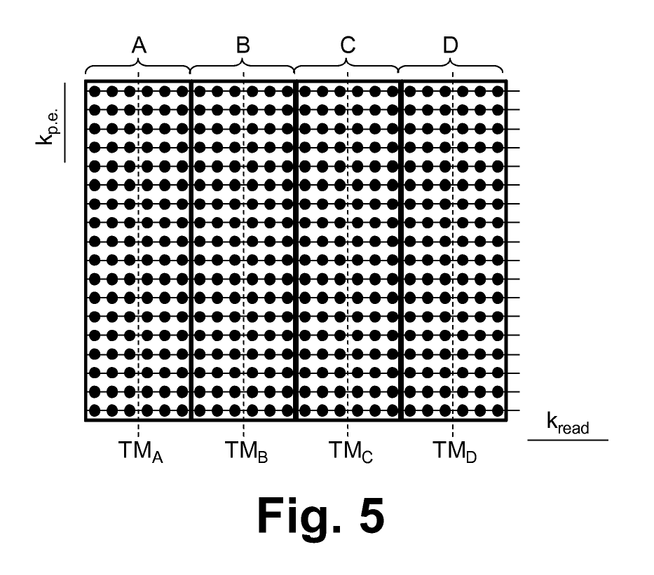

FIG. 5 diagrammatically shows Cartesian trajectories along with suitable region definitions “A”, “B”, “C”, and “D”, where each region has k-space samples with about the same measuring time designated average measuring times TM_{A}, TM_{B}, TM_{C}, TM_{D}, respectively.

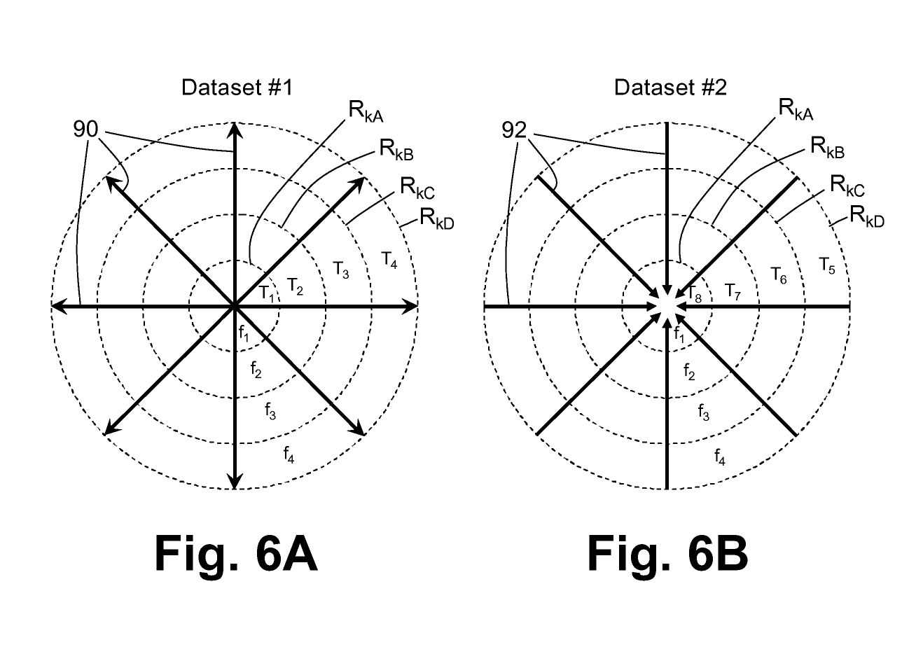

FIGS. 6A and 6B diagrammatically show radial trajectories of a first k-space dataset (“Dataset #1”) and of a second k-space dataset (“Dataset #2”) used herein to illustrate another reconstruction method that adjusts for differences in measuring time amongst the k-space samples. Datasets #1 and #2 completely overlap and use different radial trajectories providing two different measuring times for each k-space sample.

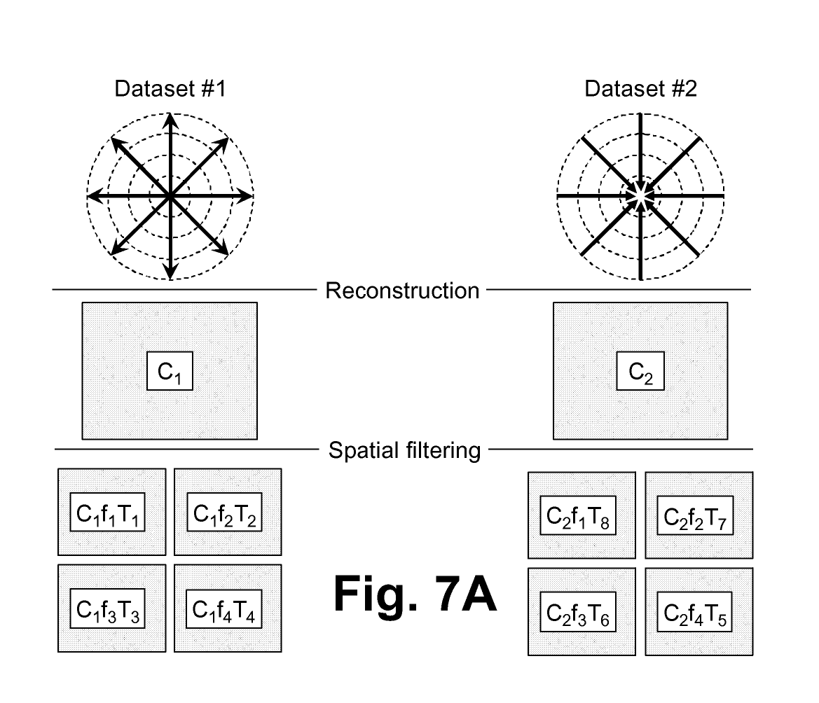

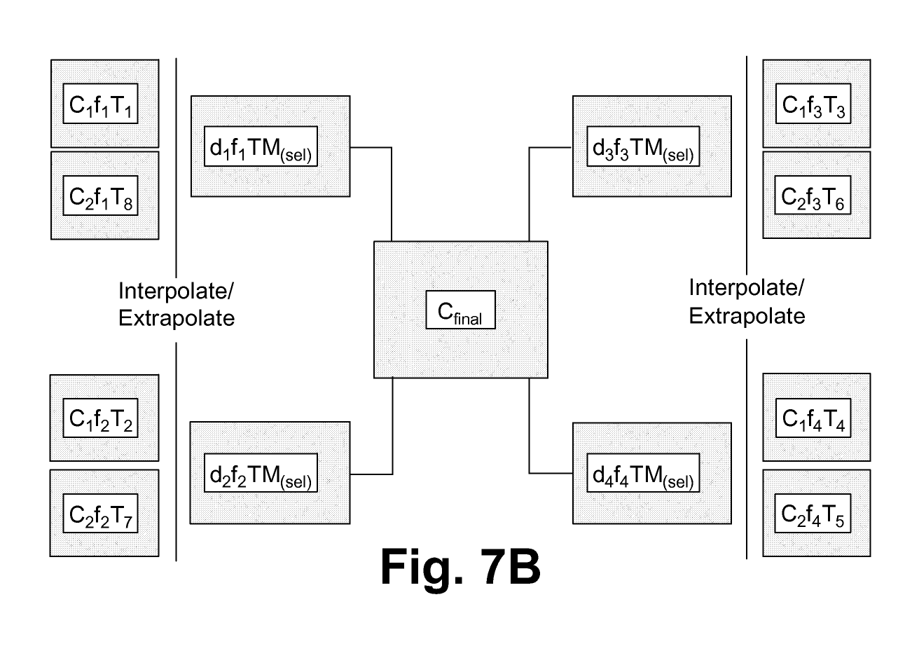

FIGS. 7A and 7B diagrammatically show a reconstruction method for reconstructing Datasets #1 and #2 to produce an image, in which differences in the measuring times of the various k-space samples are adjusted by filtering and interpolation or extrapolation performed in image space after initial reconstruction.

### DETAILED DESCRIPTION OF THE PREFERRED EMBODIMENTS

With reference to FIG. 1, a magnetic resonance imaging scanner 10 includes a housing 12 defining an examination region 14 in which is disposed a patient or other imaging subject 16. A main magnet 20 disposed in the housing 12 generates a substantially spatially and temporally constant main magnetic field in the examination region 14. Typically, the main magnet 20 is a superconducting magnet surrounded by cryoshrouding 24; however, a resistive main magnet can also be used. Magnetic field gradient coils 30 are arranged in or on the housing 12 to superimpose selected magnetic field gradients on the main magnetic field within the examination region 14. Typically, the magnetic field gradient coils 30 include a plurality of coils for generating magnetic field gradients in a selected direction and at a selected gradient strength within the examination region 14. For example, the gradient coils 30 may include x-, y-, and z-gradient coils that cooperatively produce the selected magnetic field gradient in the selected direction. A whole-body radio frequency coil 32, such as a stripline coil disposed on an insulating dielectric former with a surrounding shield 34, a birdcage coil with rigid conductive rungs and rings, or so forth, is arranged in or on the housing 12 to inject radio frequency excitation pulses into the examination region 14 and to detect generated magnetic resonance signals. A bore liner 36 separates the coils from the examination region. Alternatively or additionally, one or more local coils (not shown) can be provided for excitation or receiving, such as a head coil, surface coil or coils array, or so forth.

A magnetic resonance imaging controller 50 executes selected magnetic resonance imaging sequences. The controller 50 operates magnetic field gradient controllers 52 coupled to the gradient coils 30 to superimpose selected magnetic field gradients on the main magnetic field in the examination region 14, and operates a radio frequency transmitter 54 coupled to the radio frequency coil 32 as shown, or to a local coil, surface coil, coils array, or so forth, to inject selected radio frequency excitation pulses at about the magnetic resonance frequency into the examination region 14. For two-dimensional imaging, the radio frequency excitation also includes a concurrent slice-selective magnetic field gradient imposed by the gradient system 30, 52.

The radio frequency excitation pulses excite magnetic resonance signals in the imaging subject 16 that are spatially radially encoded by applying a magnetic field gradient in a selected direction and with a selected gradient strength. The imaging controller 50 operates a radio frequency receiver 56 connected with the radio frequency coil 32 as shown, or to a local coil, surface coil, coils array, or so forth, to receive the radial readout magnetic resonance signals, and the received radial readout data are stored in a radial readouts data memory 60. A reconstruction processor 62 reconstructs the radial readout data stored in the radial readouts data memory 60 to produce a reconstructed image. The reconstruction processor 62 can use various image reconstruction techniques to perform the reconstruction. In one approach, the radial data is transformed into Cartesian coordinates and fast Fourier transformed to produce the reconstructed image. In another approach, filtered backprojection is used to perform the image reconstruction.

During image reconstruction, a measuring time (TM) corrector 63, such as an algorithm to implement the processing methods described below, of the reconstruction processor 62 estimates values of k-space data or intermediate reconstructed image elements at a common selected measuring time. The measuring times of the k-space samples across a readout line are not identical due to the finite time required to acquire the radial readout line. Materials having rapid magnetic resonance signal decay times may have substantial signal differences amongst the k-space samples caused by the differences in measuring times. Similarly, a slow radial readout trajectory can result in substantial signal differences caused by differences in measuring times. As will be described, by interpolating or extrapolating k-space samples or intermediate image elements to a common selected measuring time based on one or more empirically fitted parameterized magnetic resonance decay functions, such signal differences can be substantially compensated to improve image quality.

The reconstructed image is stored in an images memory 64, and can be displayed on a user interface 66, transmitted over a local area network or the Internet, printed by a printer, or otherwise utilized. In the illustrated embodiment, the user interface 66 also enables a radiologist or other user to interface with the imaging controller 50. In other embodiments, separate user interfaces are provided for operating the scanner 10 and for displaying or otherwise manipulating the reconstructed images.

The described magnetic resonance imaging system is an illustrative example. In general, substantially any magnetic resonance imaging scanner can perform the image acquisition and reconstruction techniques disclosed herein or their equivalents. For example, the scanner can include an open magnet, a vertical bore magnet, a low-field magnet, a high-field magnet, or so forth.

With reference to FIGS. 2A and 2B, in one illustrated embodiment the k-space samples are acquired along radial readout lines. Each radial readout line is acquired by exciting magnetic resonance in a two-dimensional plane by applying a radio frequency excitation pulse in conjunction with a slice-selective magnetic field gradient; or in a three-dimensional volume by applying a radio frequency excitation pulse without a slice-selective magnetic field gradient. Each radial readout line is acquired using a selected magnetic field gradient along the direction of the radial readout line. In general, the relationship between the k-space trajectory, k_{read}(t), and the readout magnetic field gradient, G_{read}(t), is given by:
k_{read}(t)=γ∫G_{read}(t)·dₜ (1),
where in Equation (1) γ is the gyromagnetic ratio. Accordingly, as the readout magnetic field gradient is ramped up, the k-space trajectory moves outwardly from k-space center. FIG. 2A depicts a radial Dataset I in which data is collected for each radial readout line 70 along a trajectory starting at k=0 and extending outwardly through a central region “A” bounded by a k-space radius R_{kA}, through a first annular k-space region “B” bounded by inner and outer radii R_{kA} and R_{kB}, through a second annular k-space region “C” bounded by inner and outer radii R_{kB} and R_{kC}, and finally through an outer annular k-space region “D” bounded by inner and outer radii R_{kC} and R_{kD}. FIG. 2B depicts a radial Dataset II in which data is collected for each radial readout line 72 along a trajectory starting at the k-space radial position R_{kA} and extending outwardly through the annular k-space regions “B”, “C”, and “D”, terminating at the outermost radius R_{kD}. Dataset II does not sample the central region “A”. The two Datasets I and II are partially overlapping datasets each including k-space samples acquired at different measuring times and including common locations in k-space regions “B”, “C”, and “D” that are sampled at different measuring times in the acquired k-space Datasets I and II.

The geometry of the k-space regions “A”, “B”, “C”, and “D” depends upon whether the radial lines are acquired in a two-dimensional slice or in a three-dimensional volume. For two-dimensional slice acquisition, region “A” is circular in shape, and regions “B”, “C”, and “D” are annular in shape. For three-dimensional volume acquisition, region “A” is spherical in shape, and regions “B”, “C”, and “D” have spherical shell shapes.

With reference to Equation (1) and FIGS. 2A and 2B, and with further reference to FIGS. 3A and 3B, by varying the strength of the readout magnetic field gradient G_{read}(t), the speed of the k-space trajectory k_{read}(t) can be changed or varied. For example, the readout lines 70 of Dataset I may be acquired using a constant readout magnetic field gradient profile having a lower strength than a constant readout magnetic field gradient profile used for acquiring the readout lines 72 of Dataset II. As a result, the readout lines 70 of Dataset I will be acquired more slowly than the readout lines 72 of Dataset II. Alternately, the readout lines 72 of Dataset II may be acquired with less timing delay after the excitation RF pulse than the amount of timing delay used when acquiring readout lines 70 of Dataset I. For materials having a rapid magnetic resonance decay time, it follows that for a given k-space position the magnetic resonance signal will decay more for a k-space sample acquired in Dataset I than for the corresponding k-space sample acquired in Dataset II. This is depicted in FIGS. 3A and 3B which show generally decaying exponential magnetic resonance decay functions for the readout lines of Datasets I and II, respectively. For example, a k-space location at about the center of the annular region “B” is acquired at about a measuring time TM₂ in Dataset I, while the same k-space location is acquired at about a measuring time TM₁ in Dataset II. A k-space location at about the center of the annular region “C” is acquired at about a measuring time TM₃ in Dataset I, while the same k-space location is acquired at about the measuring time TM₂ in Dataset II. A k-space location at about the center of the outer annular region “D” is acquired at about a measuring time TM₄ in Dataset I, while the same k-space location is acquired at about the measuring time TM₃ in Dataset II. A k-space location in region “A” at a radius of about R_{kA}/2 is acquired at about the measuring time TM₁ in Dataset I. As noted previously, k-space locations in the central region “A” are not acquired in Dataset II.

The readout magnetic field gradient profiles can be time-varying rather than uniform in time. For example, in some embodiments the readout magnetic field gradient strength initially ramps up rapidly (for example, in region “A”) so as to rapidly traverse the central region of k-space, then monotonically decreases further out (for example, in regions “B”, “C”, and “D”) so as to sample more slowly. Time-varying magnetic field gradient profiles can have certain advantages in reducing SNR and in sampling more uniformly in Cartesian coordinate space. Non-uniform magnetic field gradient profiles are readily tailored to acquire at least partially overlapping k-space datasets including common locations in k-space that are sampled at different measuring times in the acquired k-space datasets. Moreover, the overlap can be other than that shown in FIGS. 2A and 2B. For example, in some embodiments the Dataset I may include sampling of regions “A”, “B”, and “C”, but not region “D”.

With continuing reference to FIGS. 1, 2A, 2B, 3A and 3B, and with further reference to FIG. 4, in some embodiments the measuring time (TM) corrector 63 of the reconstruction processor 62 interpolates or extrapolates k-space values to the common selected measuring time based on the sampling at different measuring times of common locations in k-space in the regions “B”, “C”, and “D”. In the illustrated embodiment of FIGS. 2A, 2B, 3A, 3B, and 4, the common measuring time (T₍ₛₑₗ₎) is selected as TM₁. In a process operation or algorithm 80, k-space is divided into a plurality of k-space regions, such as the illustrated regions “A”, “B”, “C”, and “D”. Each region is acquired at about a corresponding average measuring time. For Dataset #1, k-space samples in region “A” are acquired at about an average measuring time TM₁, which is the common selected measuring time TM₍ₛₑₗ₎. In accordance with a process operation or algorithm 82, therefore, the k-space samples in region “A” are kept as acquired in Dataset I. Similarly, k-space samples in region “B” are acquired at about an average measuring time TM₁ in Dataset II, which is the common selected measuring time TM₍ₛₑₗ₎. In accordance with the process operation 82, therefore, the k-space samples in region “B” are kept as acquired in Dataset II.

For regions “C” and “D”, neither Dataset I nor Dataset II acquires these regions at about the common measuring time TM₍ₛₑₗ₎ selected as TM₁. Hence, in process operation or algorithm 84, these k-space samples are extrapolated to the earlier common selected measuring time TM₁. For example, if TM₁=1 millisecond, TM₂=2 milliseconds, TM₃=3 milliseconds, and TM₄=4 milliseconds, then one suitable mathematical formula for the extrapolating of k-space samples in region “C” is:
S_{C}(TM₁)=2·S_{C}(TM₂)−S_{C}(TM₃) (2),
where S_{C}(TM₂) is a k-space sample in region “C” from Dataset II measured at about TM₂, S_{C}(TM₃) is a corresponding k-space sample in region “C” from Dataset I measured at about TM₃, and S_{C}(TM₁) is the extrapolated value at measuring time TM₁. Similarly, for extrapolating k-space samples in region “D”:
S_{D}(TM₁)=3·S_{D}(TM₃)−2·S_{D}(TM₄) (3),
where S_{D}(TM₃) is a k-space sample in region “D” from Dataset II measured at about TM₃, S_{D}(TM₄) is a corresponding k-space sample in region “D” from Dataset I measured at about TM₄, and S_{D}(TM₁) is the extrapolated value at measuring time TM₁.

More generally, for an arbitrary region “X”, a suitable linear interpolation or extrapolation formula is:
S_{X}(T₍ₛₑₗ₎)=C_{I}·S_{X}(Dataset I)+C_{II}·S_{X}(Dataset II) (4),
where S_{X}(Dataset I) is a k-space sample in region “X” from Dataset I, Sx(Dataset II) is a corresponding k-space sample in region “X” from Dataset II, and C_{I} and C_{II} are coefficients selected to provide the interpolated or extrapolated k-space sample S_{X}(T₍ₛₑₗ₎) at the selected measuring time T₍ₛₑₗ₎ for the region X. The coefficients C_{I} and C_{II} are given by:

$$\begin{matrix}{C}_{I} = ( \frac{{T}_{( sel )} - {T}_{II}}{{T}_{I} - {T}_{II}} ) , & ( 5 ) \\ and & \\ {C}_{II} = ( \frac{{T}_{( sel )} - {T}_{I}}{{T}_{II} - {T}_{I}} ) , & ( 6 )\end{matrix}$$

where T_{I} and T_{II} are the average measuring times for region “X” in Dataset I and Dataset II, respectively.

In a process operation or algorithm 86, the samples having measuring times of about TM(se,) are combined to provide a complete dataset that is reconstructed by the reconstruction processor 62 to produce a reconstructed image representative of a selected measuring time T₍ₛₑₗ₎=TM₁. The complete dataset includes: (i) the as-acquired k-space samples from region “A” measured in Dataset I; (ii) the as-acquired k-space samples from region “B” measured in Dataset II; and (iii) the extrapolated k-space samples from regions C and D output by the process operation 84.

The embodiment illustrated in FIGS. 2A and 2B, 3A and 3B, and 4 is an example. In some embodiments, the common selected time T₍ₛₑₗ₎ may be intermediate between acquired measuring times, in which case the same general formulae can be used for interpolation rather than extrapolation. Moreover, the magnetic resonance decay can be modeled using functions other than the linear functions of Equations (2), (3), and (4). For example, a decaying exponential model can be used for the extrapolation, using a modified function derived from Equation (4):
log[S_{X}(TM₁)]=C_{I}·log[S_{X}(Dataset I)]+C_{II}·log[S_{X}(Dataset II)] (7),
where log[ ] is the logarithm function. In some embodiments, the interpolation or extrapolation is applied to the complex-valued k-space samples to account for both amplitude decay and phase accrual by fitting a complex decay to the available time points, and then extrapolating back to the selected measuring time.

More or fewer than four k-space regions can be employed, and the regions do not need to be equally spaced in k-space as illustrated in FIGS. 2A and 2B. Indeed, it may be advantageous to choose smaller regions of k-space wherever the measurement time varies more rapidly as a function of the k-space location. In the limit, the number of regions can equal the number of k-space locations to be interpolated or extrapolated, so that each k-space location is interpolated or extrapolated using its own coefficients C_{I}, C_{II} computed using Equations (5) and (6) where T_{I} and T_{II} are the measuring times for samples of a k-space location in Datasets I and II, respectively. The described interpolation or extrapolation using two samples at a common k-space location are readily extended to interpolation or extrapolation using three or more samples at a given k-space location.

It is appreciated that when processing is done upon k-space data, abrupt discontinuities may potentially lead to ringing or ghosting artifacts in the subsequent reconstructed images. While the data within each dataset may have a continuous nature to it, the interpolation coefficients as discussed so far may exhibit a discontinuous nature at the boundary of each k-space region. Thus, the method may be easily extended to provide an overlap transition area of one interpolation region relative to the next, and an amplitude tapering of the acquired k-space data as that transition area is traversed. Likewise, a continuous taper of the interpolation coefficients or extrapolation coefficients may be applied across a transition region in k-space.

With reference to FIG. 5, the acquisitions can employ trajectories other than radial. For example, FIG. 5 diagrammatically shows Cartesian trajectories along with suitable region definitions “A”, “B”, “C”, and “D”. Each region has k-space samples with about the same measuring time: region “A” has an average measuring time denoted TM_{A}; region “B” has an average measuring time denoted TM_{B}; region “C” has an average measuring time denoted TM_{C}; and region “D” has an average measuring time denoted TM_{D}. In an approach for generating multiple datasets analogous to that of FIGS. 2A and 2B, the regions of FIG. 5 can be sampled in one dataset starting at the left-hand edge of region “A” and progressing to the right through regions “B”, “C”, and “D”; and sampled in another dataset starting at the left-hand edge of region “B” and progressing to the right through regions “C” and “D” without ever sampling region “A”. Alternatively, each k-space line in Cartesian space can be sampled in a left-to-right direction followed by readout gradient reversal and sampling in the right-to-left direction to common k-space locations samples at two different sampling times.

With reference to FIGS. 6A and 6B, in other embodiments the interpolation or extrapolation is performed on intermediate image elements rather than in k-space. FIGS. 6A and 6B show Dataset #1 and Dataset #2, respectively, which overlap completely in k-space. For Dataset #1, radial readout lines 90 are initiated after a radio frequency excitation pulse (including a slice-selective magnetic field gradient for two-dimensional imaging, or omitting a slice-selective gradient for three-dimensional imaging), extend outwardly from k-space center through radii R_{kA}, R_{kB}, and R_{kC}, in that order, and terminate at R_{kD}. An inner k-space region bounded by R_{kA} and containing k-space center corresponds to k-space samples in a lowest spatial frequency range f₁ that includes d.c. frequency. A first annular k-space region bounded by radii R_{kA} and R_{kB} corresponds to k-space samples in a higher spatial frequency range f₂. A second annular k-space region bounded by radii R_{kB} and R_{kC} corresponds to k-space samples in a still higher spatial frequency range f₃. An outermost annular k-space region bounded by radii R_{kC} and R_{kD} corresponds to k-space samples in a highest spatial frequency range f₄. Dataset #2 is then acquired by reversing the readout magnetic field gradient direction and acquiring radial readout lines 92 extending inwardly from the outermost radius R_{kD} through radii R_{kC}, R_{kB}, and R_{kA}, in that order, and terminating at k-space center.

The f₁ k-space region is acquired in Dataset #1 at an average measuring time T₁, and is acquired in Dataset #2 at an average measuring time T₈. The f₂ k-space region is acquired in Dataset #1 at an average measuring time T₂, and is acquired in Dataset #2 at an average measuring time T₇. The f₃ k-space region is acquired in Dataset #1 at an average measuring time T₃, and is acquired in Dataset #2 at an average measuring time T₆. The f₄ k-space region is acquired in Dataset #1 at an average measuring time T₄, and is acquired in Dataset #2 at an average measuring time T₅. The ordering of the average measuring times is: T₁<T₂<T₃<T₄<T₅<T₆<T₇<T₈.

With reference to FIG. 7A, the Datasets #1 and #2 are reconstructed into an image at a common selected measuring time as follows. Dataset #1 is reconstructed into a single complex-valued intermediate image denoted C₁, without regard to the differences in measuring time amongst the k-space samples. Similarly, Dataset #2 is reconstructed into a single complex-valued intermediate image denoted C₂, also without regard to the differences in measuring time amongst the k-space samples.

The intermediate image C₁ is spatially filtered to extract four filtered images: image [C₁f₁T₁] representing k-space samples corresponding to the frequency range f₁ and acquired at average measuring time T₁; image [C₁f₂T₂] representing k-space samples corresponding to the frequency range f₂ and acquired at average measuring time T₂; image [C₁f₃T₃] representing k-space samples corresponding to the frequency range f₃ and acquired at average measuring time T₃; and image [C₁f₄T₄] representing k-space samples corresponding to the frequency range f₄ and acquired at average measuring time T₄.

Similarly, the intermediate image C₂ is spatially filtered to extract four filtered images: image [C₂f₁T₈] representing k-space samples corresponding to the frequency range f₁ and acquired at average measuring time T₈; image [C₂f₂T₇] representing k-space samples corresponding to the frequency range f₂ and acquired at average measuring time T₇; image [C₂f₃T₆] representing k-space samples corresponding to the frequency range f₃ and acquired at average measuring time T₆; and image [C₂f₄T₅] representing k-space samples corresponding to the frequency range f₄ and acquired at average measuring time T₅.

Each of the filtered images represents a limited spatial frequency range. Since k-space radius has a direct correspondence with spatial frequency, it follows that each filtered image represents a limited k-space range (within the selectivity of the spatial filtering). For two-dimensional slice acquisition, the filtered images [C₁f₁T₁] and [C₂f₁T₈] represent the circular k-space region inside of radius R_{kA}, while the remaining filtered images represent annular k-space regions. For three-dimensional volume acquisition, the filtered images [C₁f₁T₁] and [C₂f₁T₈] represent the spherical k-space region inside of radius R_{kA}, while the remaining filtered images represent spherical shell-shaped k-space regions.

With reference to FIG. 7B, interpolation or extrapolation to a common selected measuring time T₍ₛₑₗ₎ is performed by interpolating intermediate image elements of filtered images having the same spatial frequency range. Thus, the images [C₁f₁T₁] and [C₂f₁T₈] are interpolated or extrapolated on an image element-by-image element basis, the images [C₁f₂T₂] and [C₂f₂T₇] are interpolated or extrapolated on an image element-by-image element basis, and so forth. In one approach, a linear interpolation or extrapolation is performed. Linear coefficients are defined:
a₁=T₍ₛₑₗ₎−T₁ (8),
a₂=T₍ₛₑₗ₎−T₂ (9),
a₃=T₍ₛₑₗ₎−T₃ (10),
a₄=T₍ₛₑₗ₎−T₄ (11),
a₅=T₍ₛₑₗ₎−T₅ (12),
a₆=T₍ₛₑₗ₎−T₆ (13),
a₇=T₍ₛₑₗ₎−T₇ (14),
a₈=T₍ₛₑₗ₎−T₈ (15),
and interpolation or extrapolation formulae for filtered images at each frequency range f₁, f₂, f₃, f₄ are defined in terms of the linear coefficients. An interpolated or extrapolated image at the frequency range f₁ with interpolated or extrapolated measuring time T₍ₛₑₗ₎ is given by:

$$[ {d}_{1} {f}_{1} {TM}_{( sel )} ] = \frac{- {a}_{8} \cdot [ {C}_{1} {f}_{1} {T}_{1} ] + {a}_{1} \cdot [ {C}_{2} {f}_{1} {T}_{8} ]}{{a}_{1} - {a}_{8}} , \qquad ( 16 )$$

where interpolation or extrapolation Equation (16) is evaluated on an image element-by-image element basis to produce the image [d₁f₁TM₍ₛₑₗ₎]. Similarly, an interpolated or extrapolated image [d₂f₂TM₍ₛₑₗ₎] at the frequency range f₂ is interpolated or extrapolated to the measuring time T₍ₛₑₗ₎ according to:

$$[ {d}_{2} {f}_{2} {TM}_{( sel )} ] = \frac{- {a}_{7} \cdot [ {C}_{1} {f}_{2} {T}_{2} ] + {a}_{2} \cdot [ {C}_{2} {f}_{2} {T}_{7} ]}{{a}_{2} - {a}_{7}} . \qquad ( 17 )$$

An interpolated or extrapolated image [d₃f₃TM₍ₛₑₗ₎] at the frequency range f₃ is interpolated or extrapolated to the measuring time T₍ₛₑₗ₎ according to:

$$[ {d}_{3} {f}_{3} {TM}_{( sel )} ] = \frac{- {a}_{6} \cdot [ {C}_{1} {f}_{3} {T}_{3} ] + {a}_{3} \cdot [ {C}_{2} {f}_{3} {T}_{6} ]}{{a}_{3} - {a}_{6}} . \qquad ( 18 )$$

An interpolated or extrapolated image [d₄f₄TM₍ₛₑₗ₎] at the frequency range f₄ is interpolated or extrapolated to the measuring time T₍ₛₑₗ₎ according to:

$$[ {d}_{4} {f}_{4} {TM}_{( sel )} ] = \frac{- {a}_{5} \cdot [ {C}_{1} {f}_{4} {T}_{4} ] + {a}_{4} \cdot [ {C}_{2} {f}_{4} {T}_{5} ]}{{a}_{4} - {a}_{5}} . \qquad ( 19 )$$

The final image is synthesized by combining the complex interpolated or extrapolated images according to:
C_{final}=[d₁f₁TM₍ₛₑₗ₎]+[d₂f₂TM₍ₛₑₗ₎]+[d₃f₃TM₍ₛₑₗ₎]+[d₄f₄TM₍ₛₑₗ₎] (20)
where Equation (18) is evaluated on an image element-by-image element basis to produce the final image C_{final}. In general, C_{final} and all intermediate images are complex-valued; however, C_{final} is suitably converted to a magnitude image for viewing by medical personnel or other human viewers.

In FIG. 7A, two image reconstructions are performed to produce the intermediate images C₁, C₂, followed by eight filtering operations to produce the eight filtered images. Alternatively, the k-space data can be separately gridded into several k-space data spaces corresponding to the frequency bands f₁, f₂, f₃, f₄ (eight gridding operations for the two Datasets #1 and #2) followed by reconstruction of each of the eight gridded data spaces (eight reconstruction operations) to produce the filtered images. In this latter case, spatial filtering is performed in k-space by the gridding into separate k-space data spaces prior to reconstruction; whereas, in the former case illustrated in FIG. 7A, reconstruction is performed first followed by spatial filtering in image space. Whether to separate the data into the frequency ranges f₁, f₂, f₃, f₄ before or after reconstruction is suitably selected based on computational efficiency and speed. If the reconstruction is slow compared to spatial filtering, the illustrated embodiment of FIG. 7A advantageously employs only two reconstructions. On the other hand, if reconstruction is efficient, then spatially filtering in k-space by gridding the k-space data into several data spaces followed by image reconstruction of each data space may be more efficient.

In these embodiments, it is anticipated that while the overlapping portions of k-space datasets may overlap as regions, they may not have sampling locations of individual k-space sample points which are exactly coincident. It is within the scope of this invention that interpolation or extrapolation between different measurement times may additionally be performed upon small neighborhoods of k-space sample points. Resampling or interpolation among nearby k-space points acquired with nearly the same measurement time may be performed to generate corresponding k-space locations between the multiplicity of overlapped datasets or partially overlapped datasets. It is also appreciated that if interpolations for measurement time corrections are performed between intermediate images as opposed to in k-space, then the pixels locations of the various intermediate images may be perfectly coincident, despite the k-space samples having been not exactly coincident, which may afford practical advantages of flexibility in prescribing the gradient readout waveshapes and sampling times of the overlapping datasets and the likes.

The invention has been described with reference to the preferred embodiments. Obviously, modifications and alterations will occur to others upon reading and understanding the preceding detailed description. It is intended that the invention be construed as including all such modifications and alterations insofar as they come within the scope of the appended claims or the equivalents thereof.

1. A magnetic resonance imaging method comprising:
acquiring a plurality of at least partially overlapping k-space datasets each including k-space samples acquired at different measuring times and including common locations in k-space that are sampled at different measuring times in the acquired k-space datasets;
reconstructing the plurality of at least partially overlapping k-space datasets to produce a reconstructed image representative of a selected measuring time; and
during the reconstructing, interpolating or extrapolating at least one of k-space values and intermediate image element values to the selected measuring time based on the sampling at different measuring times of the common locations in k-space.

2. The magnetic resonance imaging method as set forth in claim 1, wherein the plurality of at least partially overlapping k-space datasets are radially acquired datasets, and the interpolating or extrapolating includes:
dividing the common locations in k-space that are sampled at different measuring times into one or more k-space regions each of which is a contiguous circular, spherical, annular, or spherical shell region, the interpolating or extrapolating of k-space values or intermediate image element associated with each k-space region using an extrapolation function configured for that k-space region.

3. The magnetic resonance imaging method as set forth in claim 2, wherein the dividing of the common locations in k-space that are sampled at different measuring times into one or more k-space regions includes:
reconstructing each of the plurality of at least partially overlapping k-space datasets to produce corresponding intermediate images; and
spatially filtering each intermediate image to produce a plurality of filtered images, each filtered image being band-limited to a spatial frequency band corresponding to one of the k-space regions, the interpolating or extrapolating being performed on intermediate image elements of filtered images reconstructed from different k-space datasets and corresponding to the same k-space region.

4. The magnetic resonance imaging method as set forth in claim 1, wherein the interpolating or extrapolating includes:
interpolating or extrapolating k-space values of the common locations in k-space to the selected measuring time.

5. The magnetic resonance imaging method as set forth in claim 4, wherein the interpolating or extrapolating uses a function selected from a group consisting of:
an exponential function, and
a linear function.

6. The magnetic resonance imaging method as set forth in claim 4, wherein the interpolating or extrapolating of k-space values includes:
dividing the common locations in k-space that are sampled at different measuring times into one or more k-space regions, the interpolating or extrapolating in each k-space region using a mathematical formula designed for that k-space region.

7. The magnetic resonance imaging method as set forth in claim 6, wherein the interpolating or extrapolating in each k-space region using a mathematical formula designed for that k-space region includes:
selecting coefficients of a mathematical formula for each k-space region that provide interpolating or extrapolating for that k-space region; and
interpolating or extrapolating k-space values of the common locations in each k-space region using the mathematical formula with the coefficients selected for that k-space region.

8. The magnetic resonance imaging method as set forth in claim 6, wherein the plurality of at least partially overlapping k-space datasets are radially acquired datasets, and each of the one or more k-space regions is a contiguous circular, spherical, annular, or spherical shell region.

9. The magnetic resonance imaging method as set forth in claim 4, wherein the reconstructing includes:
generating a derived k-space dataset including the interpolated or extrapolated k-space values of the common locations in k-space at the selected measuring time, the derived k-space dataset being representative of the selected measuring time; and
reconstructing the derived k-space dataset to produce the reconstructed image representative of the selected measuring time.

10. The magnetic resonance imaging method as set forth in claim 9, wherein at least some k-space samples of the plurality of at least partially overlapping k-space datasets are acquired at about the selected measuring time, and the generating of the derived k-space dataset further includes:
combining the interpolated or extrapolated k-space values of the common locations in k-space at the selected measuring time and the k-space samples that are acquired at about the selected measuring time to generate the derived k-space dataset.

11. The magnetic resonance imaging method as set forth in claim 10, wherein the k-space samples that are acquired at about the selected measuring time are contained in one or more non-overlapping portions of the plurality of at least partially overlapping k-space datasets.

12. The magnetic resonance imaging method as set forth in claim 1, wherein the plurality of at least partially overlapping k-space datasets are radially acquired datasets, and the interpolating or extrapolating includes:
reconstructing and spatially filtering the plurality of at least partially overlapping k-space datasets to produce intermediate image elements at least some of which are common intermediate image elements having about the same spatial position and spatial frequency but different measuring times; and
interpolating or extrapolating the common intermediate image elements to produce derived intermediate image elements at the selected measuring time.

13. The magnetic resonance imaging method as set forth in claim 12, wherein the reconstructing includes:
combining at least the derived intermediate image elements to produce the reconstructed image representative of the selected measuring time.

14. The magnetic resonance imaging method as set forth in claim 13, wherein at least some intermediate image elements have about the selected measuring time, and the combining further includes:
combining the derived intermediate image elements and the intermediate image elements having about the selected measuring time to produce the reconstructed image representative of the selected measuring time.

15. The magnetic resonance imaging method as set forth in claim 12, wherein the interpolating or extrapolating uses a function selected from a group consisting of:
an exponential function, and
a linear function.

16. The magnetic resonance imaging method as set forth in claim 12, wherein the reconstructing and spatial filtering includes:
reconstructing each of the plurality of at least partially overlapping k-space datasets to produce corresponding first intermediate images; and
spatially filtering each first intermediate image to produce a plurality of filtered images, each filtered image being band-limited to a spatial frequency band and being representative of an average measuring time.

17. The magnetic resonance imaging method as set forth in claim 16, wherein the interpolating or extrapolating of the common intermediate image elements to produce derived intermediate image elements at the selected measuring time includes:
interpolating or extrapolating the common intermediate image elements of each spatial frequency band using a mathematical formula designed for that spatial frequency band.

18. The magnetic resonance imaging method as set forth in claim 12, wherein the reconstructing and spatial filtering includes:
separating each of the at least partially overlapping k-space datasets into several k-space data spaces corresponding to a plurality of spatial frequency bands; and
reconstructing each k-space data space into a filtered image, each filtered image being band-limited to the spatial frequency band of the reconstructed data space and being representative of an average measuring time.

19. The magnetic resonance imaging method as set forth in claim 18, wherein the interpolating or extrapolating of the common intermediate image elements to produce derived intermediate image elements at the selected measuring time includes:
interpolating or extrapolating the common intermediate image elements of each spatial frequency band using a mathematical formula designed for that spatial frequency band.

20. A magnetic resonance imaging apparatus for performing the method of claim 1.

21. A magnetic resonance imaging apparatus comprising:
a main magnet for generating a temporally constant main magnetic field through an examination region);
gradient field coils for generating magnetic field gradients in the examination region;
at least radio frequency coils for transmitting radio frequency signals into the examination region and receiving induced resonance signals from the examination region;
a magnetic resonance imaging controller which controls the gradient coils and the radio frequency coils to acquire a plurality of at least partially overlapping k-space datasets each including k-space samples acquired at different measuring times and including common locations in k-space that are sampled at different measuring times in the acquired k-space datasets;
a reconstruction processor which reconstructs the plurality of at least partially overlapping k-space datasets to produce a reconstructed image representative of a selected measuring time, the reconstruction processor including a measuring time correction algorithm which during the reconstructing, interpolates or extrapolates at least one of k-space values and intermediate image element values to the selected measuring time based on the sampling at different measuring times of the common locations in k-space.
